(19) United States
(12) Patent Application Publication
(10) Pub. No.: US 2005/0024686 A1
(43) Pub. Date: Feb. 3, 2005

(54) Image data recording method and apparatus, and image displaying method and apparatus

(76) Inventors: Takayuki Ilda, Kanagawa (JP); Yoichi Nakamura, Kanagawa (JP); Masaki Takamatsu, Kanagawa (JP); Shizuo Habuta, Tokyo (JP); Tatsuya Konagaya, Kanagawa (JP)

Correspondence Address: BIRCH STEWART KOLASCH & BIRCH, PO BOX 747, FALLS CHURCH, VA, 22040-0747, US

(21) Appl. No.: 10/901,185

(22) Filed: Jul. 29, 2004

(30) Foreign Application Priority Data
Jul. 31, 2003 (JP) 2003-205113

(51) Int. Cl. H04N 1/21; G03F 3/08

(52) U.S. Cl. 358/302; 358/523

(57) ABSTRACT

A photo digitizer records image data of an image frame. In the photo digitizer, a DVD recorder writes the image data to a DVD medium for respectively image frames obtained by reading from photo film. The DVD recorder writes information of piece number of plural film pieces to the DVD at addresses where the image frames are associated with respectively one of the film pieces. The film pieces constitute the photo film. Furthermore, a display panel displays image frames of photo film. A controller reads image data of the image frames from a DVD, and reads information of piece number of a film piece from the DVD. The display panel is controlled to arrange the image frames per the film piece.

### BACKGROUND OF THE INVENTION

1. Field of the Invention

The present invention relates to an image data recording method and apparatus, and image displaying method and apparatus. More particularly, the present invention relates to an image data recording method and apparatus in which image frames can be written in a well sorted manner, and image displaying method and apparatus capable of displaying image frames in the sorted manner.

2. Description Related to the Prior Art

A photo digitizing system service is known, in which image frames of photo film such as negative photo film are converted digitally into digital image data, which are written to a storage medium, such as a CD (compact disk) medium or DVD (digital versatile disk) medium. A customer or user is supplied with the storage medium. Photographs being converted to the image data, degradation of image quality with time can be prevented. Furthermore, the storage medium according to recent techniques has had a very great capacity, so that a great number of the image frames can be stored therein. In comparison with direct observation of photographic prints, a remarkable advantage arises in that a great number of the image frames can be handled, searched and viewed with great ease. To this end, commercial service of the photo digitizing system has been developed quickly.

JP-A 2002-354385 discloses a photo digitizer for the photo digitizing system. The photo digitizer includes a photo film scanner and a medium drive. The photo film scanner photoelectrically reads the image frames from the photo digitizer. The medium drive responds to the output of the photo film scanner, and writes the digital image data to the storage medium. The image data of the image frames are provided with information of file names mapped thereto according to a sequence of the reading.

The digital image data of the image frames stored in the storage medium are played by running an image displaying program. Various image displaying programs are known, including one for displaying the image frames in an arranged manner in a matrix form, and another program for displaying a selected one of the image frames in enlargement, and still another program for intermittently displaying the image frames at a predetermined interval of time to present a slide show.

After the photo digitizing operation, the digital image data of the image frames are independent from one another. No chronological relationship can be found clearly between the image frames. The image frames in the plurality are combined together according to the single strip of the photo film or film piece. The combined state clarifies the relationship of the calendrical period of photography. On the other hand, the image frames in the digitized form do not have chronological relationships between, because single data files of the image frames are individual from one another.

To enjoy viewing photographs, a user may observe a certain scene in comparison with another included in the image frames and having a date being close to that of the first scene. If a close relationship between the scene is recognized and followed, the recollection of his or her past years can be deeper. However, no known technique is useful in consideration of easily establishing such close relationship between the image frames.

### SUMMARY OF THE INVENTION

In view of the foregoing problems, an object of the present invention is to provide an image data recording method and apparatus in which image frames can be written in a chronologically sorted manner, and image displaying method and apparatus capable of displaying image frames.

In order to achieve the above and other objects and advantages of this invention, an image data recording method of recording image data of an image frame to a storage medium is provided. In the method, the image frame is read from a film piece by a scanner to obtain the image data, the film piece being included in a plurality of film pieces defined by splitting of photo film, the film piece having a plurality of the image frame which is readable by the scanner. The image data is written to the storage medium together with piece discernment information for discernment of the film piece.

The piece discernment information is constituted by counted information of the film piece according to counting toward a front or rear end of the photo film in serial arrangement of the plural film pieces in an unsplit form of the photo film.

The photo film after being developed photographically is cut into a plurality of the film pieces, is contained in photo film sheaths, and the film pieces have a length adapted to a shape of the photo film sheaths.

Furthermore, the film pieces arranged in series are counted. The piece discernment information is assigned to the film pieces according to a result of the counting step.

Furthermore, the image frames are read per the film pieces. The image frames being read are counted in a range of the film pieces. Image frame discernment information is assigned to the image frames according to a result of the counting step. The image frame discernment information is written to the storage medium.

Furthermore, the film pieces are spliced together in series, to obtain a film piece group. The film piece group is transported. At least one of front and rear ends of the film pieces are detected in the film piece group being transported, the film pieces being counted upon detection of the front or rear end.

Furthermore, photo film discernment information of the photo film is written to the storage medium.

In a preferred embodiment, furthermore, information of a photographing date of the image frames is obtained by analyzing the image data according to character recognition. The information of the photographing date is written to the storage medium.

Furthermore, in case of failure of determining the photographing date, an estimated photographing period is determined. Information of the estimated photographing period being determined is written to the storage medium.

The estimated photographing period is determined by analyzing type information of a type of the photo film.

Furthermore, in case of failure of determining the photographing date, a production period is determined according to the type information, the production period being regarded as the estimated photographing period. In case of failure of determining the production period, an availability period is determined according to the type information, the availability period being regarded as the estimated photographing period.

Furthermore, the image frames are sorted per the film pieces according to the piece discernment information read from the storage medium. The image frames are displayed in a sorted manner by the film pieces.

The storage medium comprises an optical information recording medium.

Also, an image data recording apparatus for image data of an image frame is provided. An information recorder writes the image data to a storage medium, the image data being of respectively image frames obtained by reading from photo film. The information recorder writes piece discernment information of plural film pieces to the storage medium at addresses where the image frames are associated with respectively one of the film pieces, a series of the film pieces constituting the photo film.

The photo film after being developed photographically is cut into a plurality of the film pieces, is contained in photo film sheaths, and the film pieces have a length adapted to a shape of the photo film sheaths.

Furthermore, a transporting mechanism transports a film piece group of the film pieces in series. An edge sensor detects at least one of front and rear ends of the film pieces in the film piece group being transported. A controller counts the film pieces upon an output of the edge sensor, and assigns the piece discernment information to the film pieces according to a result of counting, the piece discernment information being transmitted to the information recorder.

Furthermore, an image sensor reads the image frames per the film pieces. The controller counts the image frames being read in a range of the film pieces, and assigns image frame discernment information to the image frames according to a result of counting, the image frame discernment information being written to the storage medium by the information recorder.

In a preferred embodiment, furthermore, a date image analyzer obtains information of a photographing date of the image frames by analyzing the image data according to character recognition, wherein the information recorder writes the information of the photographing date to the storage medium.

Furthermore, a period estimating unit is operated in case of failure of determining the photographing date, for determining an estimated photographing period, wherein the information recorder writes information of the estimated photographing period being determined to the storage medium.

The period estimating unit includes a storage device for storing first and second data tables. The first data table is constituted by information of a prescribed production period stored at an address of type information of one type of the photo film of which the production period is recognizable. The second data table is constituted by information of a pre-estimated availability period stored at an address of the type information of the type of the photo film irrespective of recognition of the production period thereof. The controller refers to the first data table for determining the production period according to the type information, and in case of failure of determining with the first data table, refers to the second data table for determining the availability period according to the type information, either one of the production period and the availability period being adapted to determining the estimated photographing period.

According to still another aspect of the invention, an image displaying method of displaying image frames of photo film on a display panel is provided. The image frames are arranged per film piece on the display panel, the film piece being defined by splitting of the photo film after being developed photographically.

Furthermore, image data of the image frames are read from a storage medium. The image data are sorted per the film piece.

Furthermore, piece discernment information is read from the storage medium, the piece discernment information being adapted to sorting of the image data per the film piece.

In the arranging step, at least one film piece region is determined on the display panel, to extend horizontally, and display a plurality of the image frames commonly included in the film piece.

The display panel further displays photo film discernment information of the photo film and the piece discernment information in association with the film piece region.

The at least one film piece region comprises plural film piece regions arranged vertically in series.

In the arranging step, an enlarged indicating frame region is determined on the display panel, to display a designated one of the image frames indicated in the film piece region in an enlarged size.

Furthermore, it is determined whether the piece discernment information is stored in the storage medium. In case of failure of determining the piece discernment information, the image frames are arranged on the display panel according to discernment information of the image data.

Also, an image displaying apparatus for displaying image frames of photo film on a display panel is provided, and includes a display panel. A controller reads image data of the image frames from a storage medium, reads piece discernment information of a film piece from the storage medium, the film piece being defined by splitting of the photo film after being developed photographically, and controls the display panel according to the image data and the piece discernment information, to arrange the image frames per the film piece on the display panel.

### BRIEF DESCRIPTION OF THE DRAWINGS

The above objects and advantages of the present invention will become more apparent from the following detailed description when read in connection with the accompanying drawings, in which:

FIG. 1A is an explanatory view illustrating a first half of a photo digitizing process to supply a DVD medium;

FIG. 1B is an explanatory view illustrating a second half of the photo digitizing process to use the DVD medium;

FIG. 2 is an explanatory view in plan, illustrating a group of film pieces being spliced;

FIG. 3 is a block diagram schematically illustrating a photo digitizer;

FIG. 4 is an explanatory view illustrating a table of a photo film reference information file;

FIG. 5 is a block diagram schematically illustrating storage areas for information in the DVD medium;

FIG. 6 is an explanatory view in elevation, illustrating an index menu pattern on a display panel;

FIG. 7 is an explanatory view in elevation, illustrating an enlargement menu pattern on the display panel;

FIG. 8 is a flow chart illustrating a process of photo digitization;

FIGS. 9A and 9B are a flow chart illustrating a process of playing image data;

FIG. 10 is an explanatory view illustrating a photo film reference information file with photographing dates;

FIG. 11 is an explanatory view illustrating a DX code table with a production history data table;

FIG. 12 is an explanatory view illustrating an availability history data table;

FIG. 13 is a graph illustrating distribution of times of the use of the photo film;

FIG. 14 is a flow chart illustrating a step of determining an estimated photographing period.

### DETAILED DESCRIPTION OF THE PREFERRED EMBODIMENT(S) OF THE PRESENT INVENTION

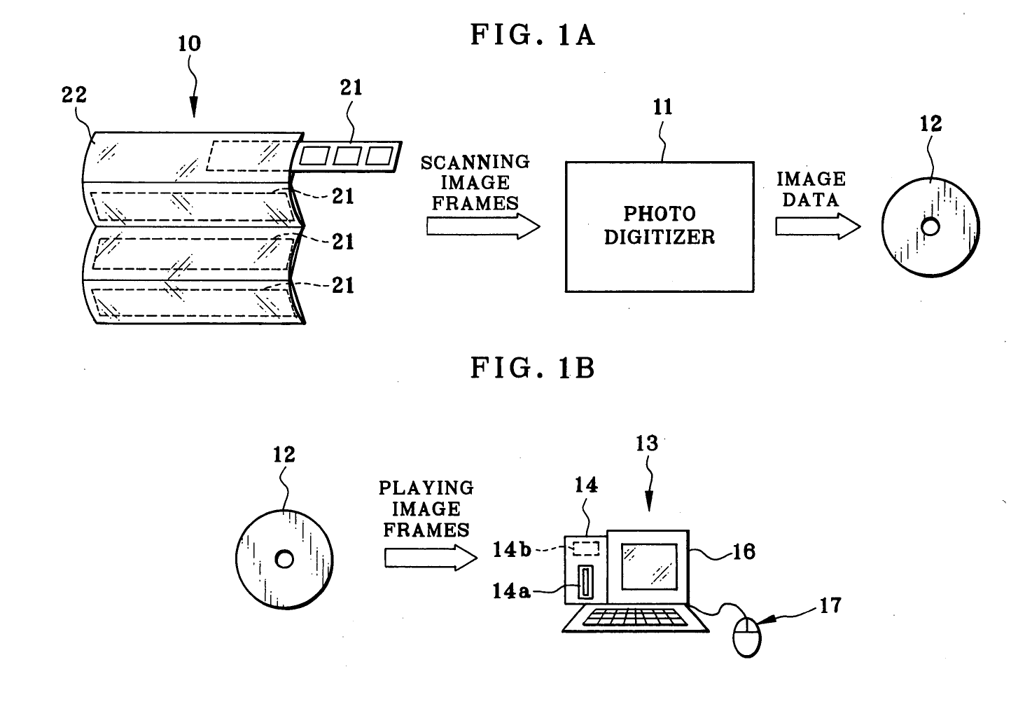

In FIGS. 1A and 1B, a photo digitizing system is schematically illustrated. In FIG. 1A, a negative photo film 10 or photo filmstrip is forwarded by a user or customer to a photo shop or photo finisher. A photo digitizer 11 is operated by the photo finisher, scans and reads image frames on the photo film 10, and digitalizes image data of image frames. A DVD medium 12 is used, to which the image data of the digital form are written by the photo digitizer 11. The photo digitizer 11 not only records image data, but a photo film reference information file with memory areas for writing a photo filmstrip number of image data of image frames. As will be described later, the photo film reference information file makes it possible to display image frames in a sorted manner per photo filmstrip on the display panel.

The DVD medium 12 after recording of the image data of image frames and photo film reference information files is supplied to the user. A personal computer 13 at the home of the user is loaded with the DVD medium 12, to play the image data to display the image frames. A DVD drive 14a is connected with a computer main unit 14 of the computer 13, and receives insertion of the DVD medium 12 set therein. Peripheral elements are connected with the computer main unit 14, including a display panel 16 and an operation panel 17 having a keyboard, mouse and the like. A PC CPU or controller 14b in the computer main unit 14 responds operation signals from the operation panel 17, runs an image displaying program, to display image frames on the display panel 16 by playing the image data.

The photo film 10 is separated in plural film pieces 21, which are contained in photo film sheaths 22 or holder for preservation at a user or customer. The photo film sheaths 22 are used respectively for the film pieces 21 and a single user order of photofinishing of the film pieces 21. The film pieces 21 have a length of recording at most six (6) image frames.

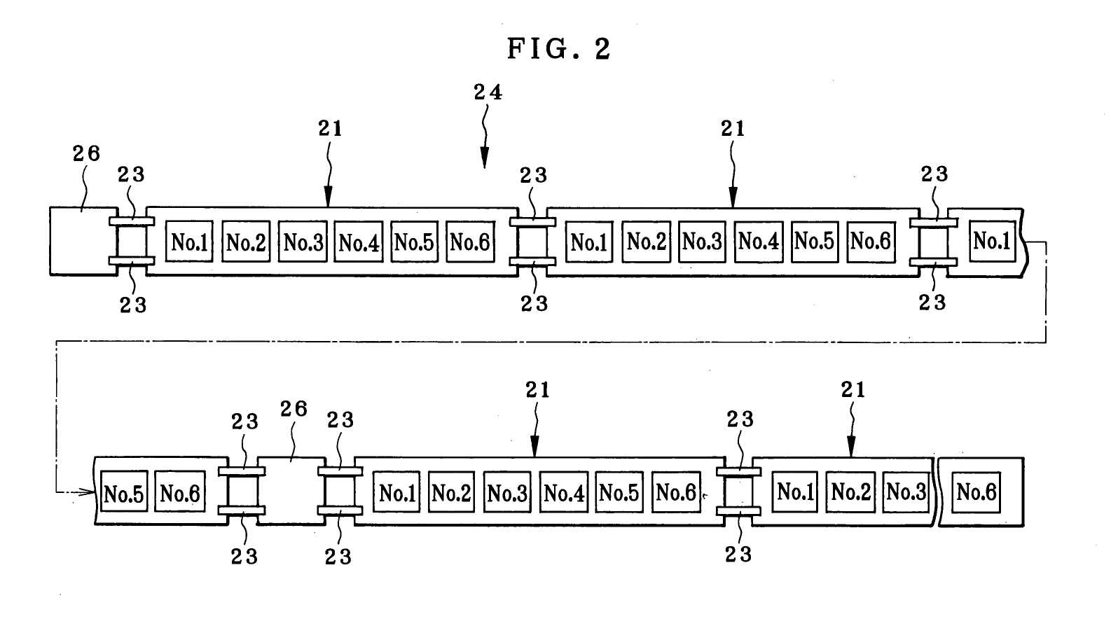

In FIG. 2, image frames of the photo film 10 are digitized by photo digitization. An operator at a photo laboratory takes the film pieces 21 out of the photo film sheaths 22. Splice tapes 23 are used and attached to the film pieces 21 for splicing. A user order film piece group 24 for a photo filmstrip of one user order is produced as a series of the film pieces 21. It is likely that a plurality of strips of the photo film 10 are associated with one user order. For this case, a leader sheet 26 is used to attachment and indication of borderlines between the strips of the photo film 10. Namely, a first one of the film pieces 21 included in the photo film 10 is provided with the leader sheet 26 attached thereto. A final one of the film pieces 21 is included in the photo film 10 is connected with a second leader sheet 26 for next strip of the photo film 10. Thus, the film piece group 24 is produced by connection of the film pieces 21 according to one user order. The film piece group 24 is set in a photo film carrier in the photo digitizer 11, and scanned consecutively for the film pieces 21 of the one user order.

User order information is recorded to the leader sheet 26, including a user information in a form of a user code, ordering date information, order number information, and photo filmstrip discernment information. The user order information is recorded in a bar code system, and is readable by the photo digitizer 11. The photo filmstrip discernment information is information for discerning plural photo filmstrips with which a single order is placed. Photo filmstrip numbers of 1, 2, 3 and so on are mapped to the photo filmstrips. For example, numbers of 1-10 are mapped to a plurality of the leader sheet 26 if ten strips of the photo film 10 is related to a single order.

In the present embodiment, a bar code is printed on the leader sheet 26 for representing information. However, any suitable system other than the bar code system may be used for storing of information with the leader sheet 26. A wireless tag, or other IC memory chip of a small type may be incorporated in the leader sheet 26. User information or the like may be written to the IC memory chip.

In the present embodiment, the plurality of the photo film 10 for one order are spliced together for forming the user order film piece group 24. However, a plurality of the photo film 10 for two or more orders may be spliced together for forming the film piece group 24, which can be scanned consecutively. The user orders are discerned according to the ordering numbers included in the user order information. If the film piece group 24 includes photo filmstrips 10 owned by plural users, obtained image data are sorted for each of the users according to the user information included in the user order information.

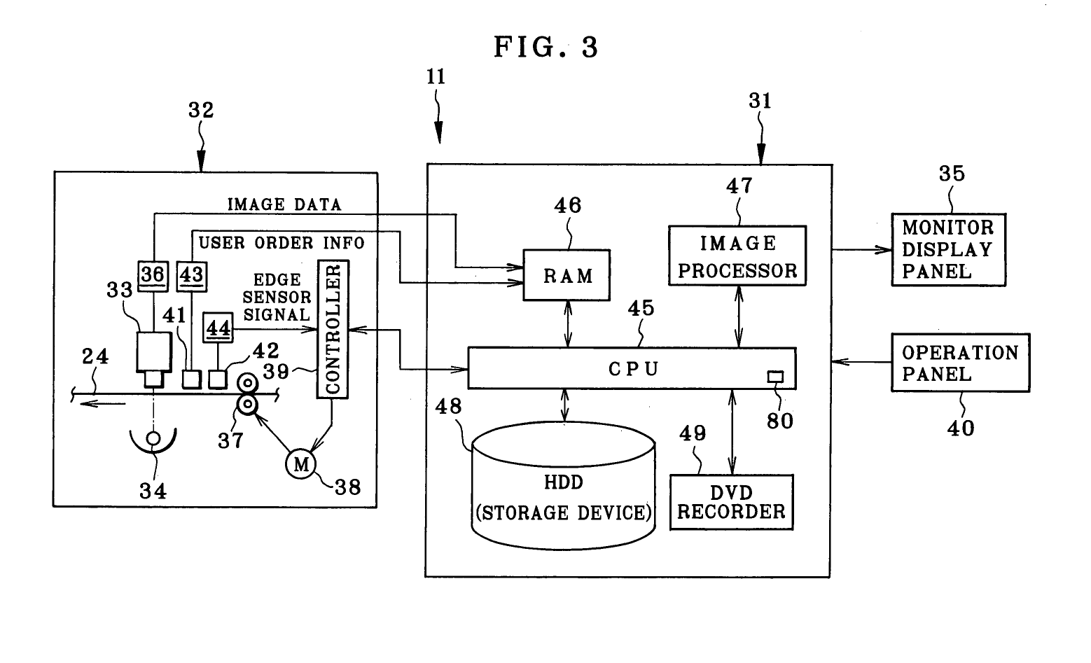

In FIG. 3, the photo digitizer 11 is schematically illustrated. The photo digitizer 11 includes a digitizer main unit 31, a scanner 32, a monitor display panel 35, and an operation panel 40. The digitizer main unit 31 is connected with the scanner 32 by an interface, for example SCSI interface, by which image data output by the scanner 32 is transmitted to the digitizer main unit 31. A control signal generated by the digitizer main unit 31 is transmitted to the scanner 32.

An area CCD camera 33 having an image sensor is incorporated in the scanner 32. A light source 34 emits detection light, which passes through the photo film 10 and is received by the CCD 33, so image frames on the user order film piece group 24 are read photoelectrically. An A/D converter 36 receives an analog output of the CCD 33, converts the output into a digital image data, which is sent to the digitizer main unit 31. Transport rollers 37 transport the film piece group 24. When image frames of the film piece group 24 respectively reach a reading position of the CCD 33, the transport of the film piece group 24 is stopped to read an image frame. Upon completion of reading one frame, the film piece group 24 is transported for one frame, to read a succeeding image frame. A transport motor 38 drives the transport rollers 37. A controller 39 controls the transport motor 38, the CCD 33, and elements included in the scanner 32.

A bar code reader 41 and an edge detecting photo sensor 42 are disposed upstream from the CCD 33. The bar code reader 41 reads the user order information recorded on the leader sheet 26. An A/D converter 43 converts the user order information to digital data, which is input to the digitizer main unit 31. The edge detecting photo sensor 42 detects an end or edge of each one of the film pieces 21, and transmits an edge sensor signal to the controller 39. The edge detecting photo sensor 42 is a photo sensor, but may be a sensor of a different type. There is an A/D converter 44 for converting the edge sensor signal to a digital signal. The controller 39 responds to the edge sensor signal, discerns ends of the film piece 21, and causes the transport motor 38 to control a moving amount of the user order film piece group 24.

In the film piece 21, image frames are arranged at a predetermined interval. In reading the respective image frames in the film piece 21, the controller 39 causes transport of the user order film piece group 24 at an amount according to the predetermined interval after reading of each one frame. Thus, a second image frame is set at the reading position of the CCD 33. However, an interval between a final frame or sixth frame of a first one of the film pieces 21 and a starting frame or first frame of a second one of the film pieces 21 is different from the above-described predetermined interval. Thus, the front and rear ends of the film pieces 21 are detected by the edge detecting photo sensor 42, to control a transported amount of the film piece group 24.

Also, an edge sensor signal from the edge detecting photo sensor 42 is sent to the digitizer main unit 31 by the controller 39. A digitizer controller or CPU 45 in the digitizer main unit 31 responds to the edge sensor signal, counts the number of the film pieces 21, and recognizes the piece number of a handled one of the film pieces 21 as a portion of the photo film 10.

The digitizer main unit 31 is basically constituted by a personal computer or workstation, and includes the digitizer CPU 45, a RAM 46, an image processor 47, a hard disk 48 or storage device as a period estimating unit, and a DVD recorder 49 or DVD drive as information recorder. The storage device may be any type other than the hard disk 48, and can be a server. Various programs are stored in the hard disk 48, including the operating system (OS), a device driver program for controlling the scanner 32, and a writing program for writing image data to the DVD medium 12.

The digitizer CPU 45 runs various programs stored in the hard disk or storage device 48, to control relevant elements of the apparatus. RAM 46 is a work memory used during execution of the programs by the digitizer CPU 45, but also stores data transmitted by the scanner 32 in a temporary manner. Image data of the image frames are written to RAM 46 temporarily. The image processor 47 subjects the image data to image processing, before the process image data is written to the hard disk 48. Examples of the image processing in the image processor 47 includes correction processing of gamma correction or the like, and data compression. Image data of the image frame is compressed according to the JPG (Joint Photographic Experts Program) format and converted in JPG files.

User order information read from the leader sheet 26 is written to RAM 46. The digitizer CPU 45 produces a photo film reference information file according to the user order information and edge sensor signal. The number of the reference information file is one for one user order. When the bar code reader 41 reads the user order information for a first time in relation to the user order film piece group 24, the digitizer CPU 45 produces a photo film reference information file newly.

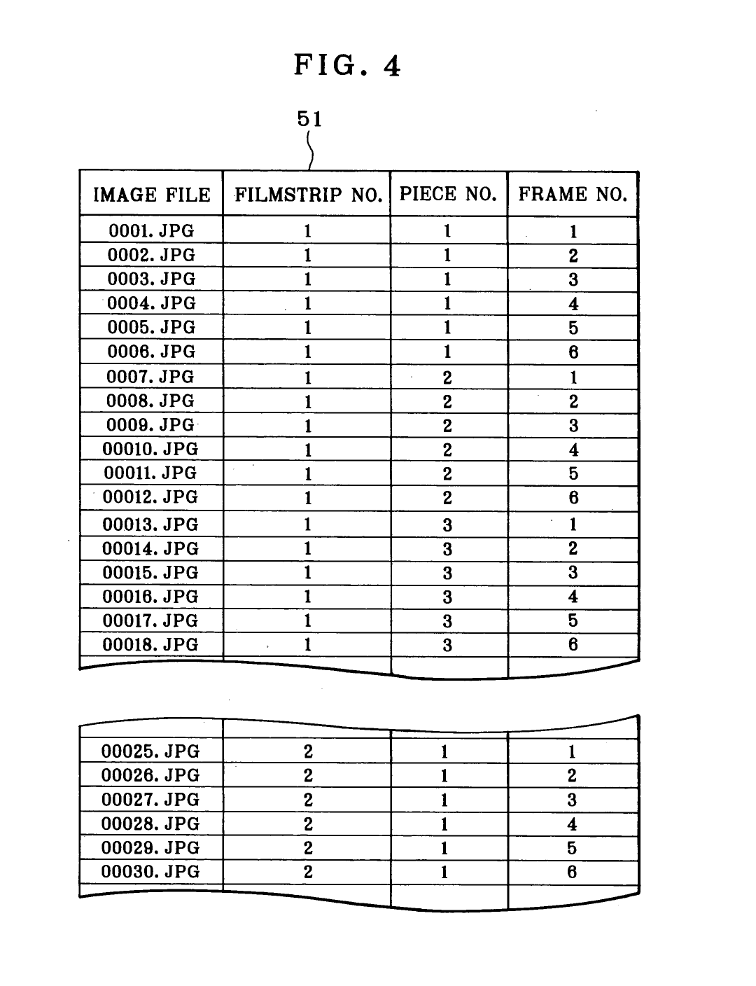

At each time that image data of one image frame is read, information is stored in areas of the reference information files at the address of the file name of the image data, the information including the photo filmstrip number, piece number and frame number. In FIG. 4, photo film reference information files 51 as piece discernment information and frame discernment information are illustrated. Image file names are mapped to the image data in an order of reading of the image frames in the photo film 10. The photo filmstrip number is to discern the photo film 10, and is mapped to the image frames in an order of reading the image frames from the user order film piece group 24. The photo filmstrip number is incrementally stepped at each time that the leader sheet 26 is detected. Upon completion of reading for one user order, the photo filmstrip number is reset. To read the film piece group 24 of a succeeding user order, the photo filmstrip number is counted up from one (1) sequentially.

The piece number is for discernment of each film piece in the photo film 10 as single strip. No. 1 is mapped to a first one of the film pieces 21 in the photo film 10. This number is stepped incrementally at each time that an end of the film pieces 21 is detected. When the entirety of the photo film 10 is read, the counting of the piece number is reset. As the frame number is for discernment of six (6) frames in each one of the film pieces 21, numbers of 1-6 are mapped to the frames of the film pieces 21 in the order of reading.

It is likely that an unrelated one of the film pieces 21 is mixed with the film pieces 21 included in the user order film piece group 24. In an ordinary state, the plurality of the film pieces 21 associated with the photo film sheaths 22 are combined to constitute the photo film 10. However, a certain film piece may be mixed in the film pieces 21 of the photo film sheaths 22. If there is an error, the photo filmstrip number may be mapped to the certain film piece even though it should be given a different photo filmstrip number.

To prevent the errors in recognition, it is preferred to read the DX code recorded on the photo film 10, to check whether two adjacent pieces in the film pieces 21 constitute the photo film 10 commonly. As is well-known in the art, the DX code has an encoded form of information of type of the photo film, level of photo sensitivity and the like. The code system is according to the ANSI (American National Standard Institute). If coincidence of the DX code is found by checking, it is confirmed that no incidental mixture of the film pieces 21 from other photo filmstrips occurs. If two differently derived pieces of the film pieces 21 are mixed, mixture information, such as time error information, can be recorded in association with image data of image frames of the film pieces 21 without mapping photo filmstrip numbers, piece numbers or frame numbers. This mixture information makes it possible to search and find the mixed pieces subsequently with great ease.

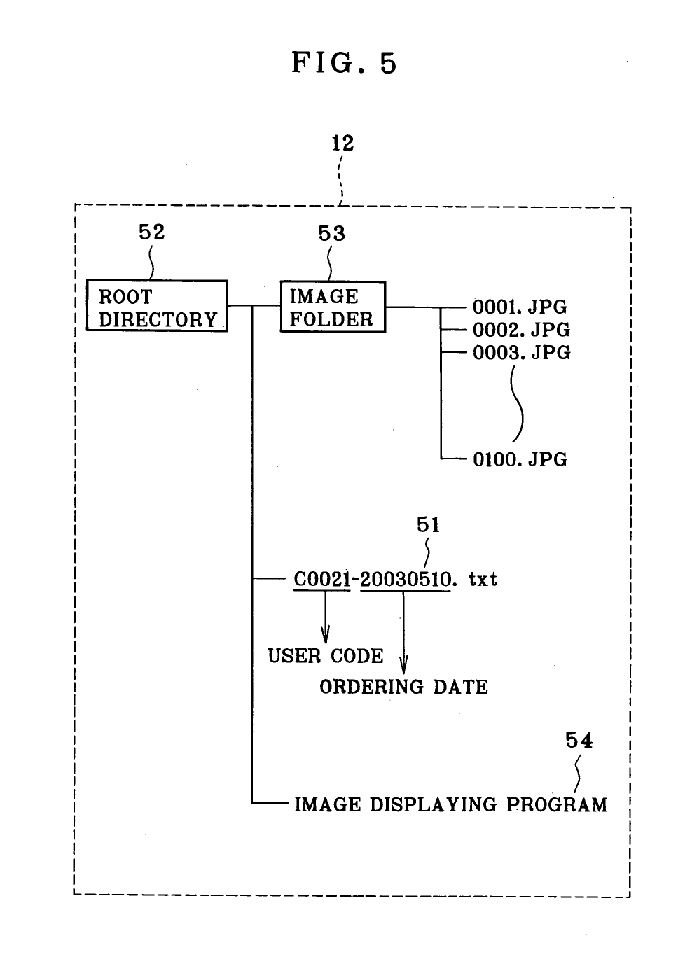

The DVD recorder 49 writes information to the DVD medium 12, the information including image data of read image frames, and the photo film reference information files 51 associated with the image data. In FIG. 5, an example of storage areas for the information to the DVD medium 12 is illustrated. There is a root directory 52 under which the photo film reference information files 51 are stored, and an image folder 53 with image data is created. The image data are stored in the image folder 53. To the photo film reference information files 51, a file name is mapped, for example, C0021-20030510. A first portion C0021 is information of a user code. A second portion 20030510 is information of an ordering date. Also, an image displaying program 54 is written to the DVD medium 12 for reproducing and displaying image frame according to image data.

The DVD medium 12 is supplied to the user together with the photo film 10. The user operates a personal computer, starts up an image displaying program 54, to play image frames on the display panel according to image data recorded in the DVD medium 12.

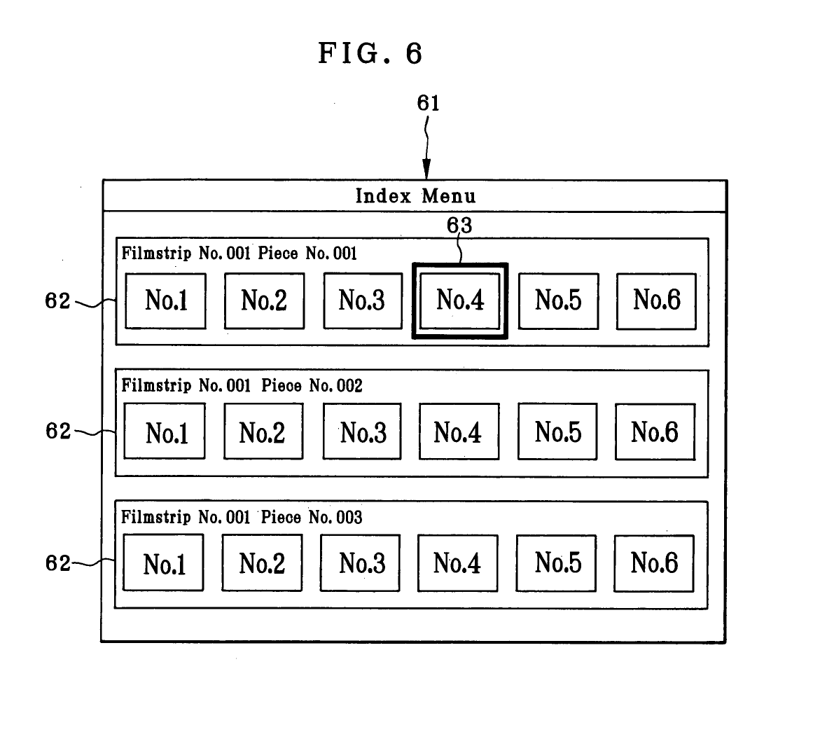

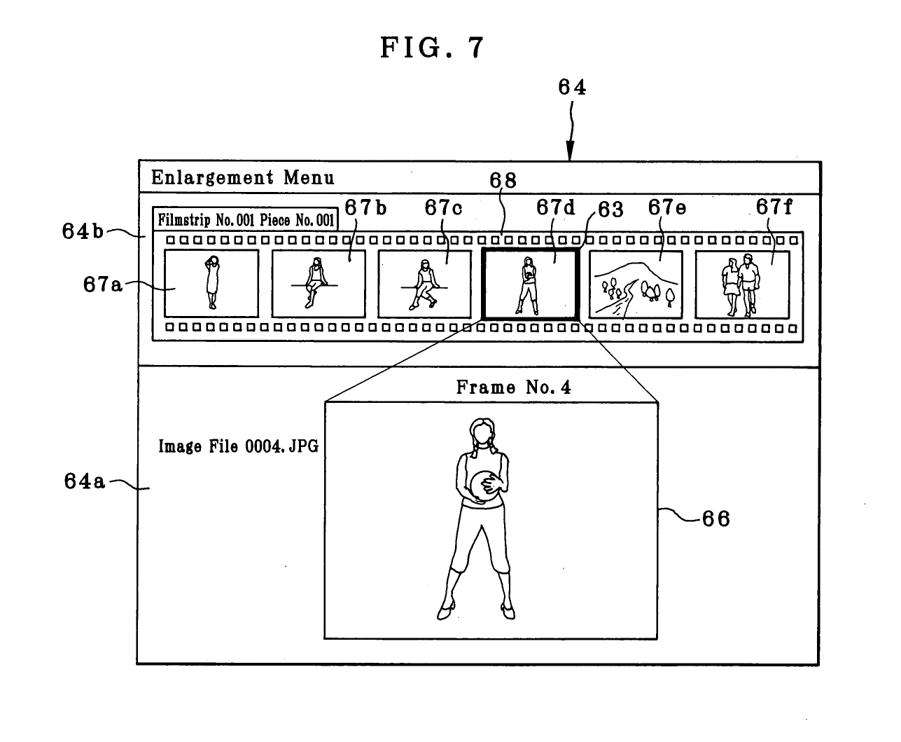

In FIGS. 6 and 7, a menu pattern of the image displaying program 54 is illustrated. When the image displaying program 54 is started up, an index menu pattern 61 is displayed on the display panel 16 of the computer 13. On the index menu pattern 61, thumbnail images of the image frames are indicated in a matrix form as read from the image folder 53. The image displaying program 54, if it is detected that the photo film reference information files 51 do not exist in the DVD medium 12, then rearranges the image frames in sequence of the file names. If the photo film reference information files 51 exist, then the image displaying program 54 sorts the image frames according to the photo film reference information files 51 to follow the photo filmstrip numbers, piece numbers and frame numbers. Six consecutive frames derived from the film pieces 21 are arranged distinctly from other material. Specifically, the image frames Nos. 1-6 are made conspicuous by a frame pattern or film piece region 62, which represents each one of the film pieces 21. Thumbnail images are indicated in the film piece region 62, where the photo filmstrip numbers and piece numbers are also indicated.

A cursor 63 is indicated in the index menu pattern 61, and shifted to click a desired one of frames for enlargement. In FIG. 7, a panel image is changed over to an enlargement menu pattern 64, to display the desired one in an enlarged form. The enlargement menu pattern 64 has two regions which are a main region or enlarged indicating frame region 64a, and a subsidiary region or film piece region 64b. The enlarged indicating frame region 64a is used to display an enlarged image frame 66 derived as a selected one of the image frames. The film piece region 64b is used to display thumbnail image frames 67a, 67b, 67c, 67d, 67e and 67f of one piece of the film pieces 21 including the enlarged image frame 66. Also, a background pattern 68 for film piece region is displayed with the thumbnail image frames 67a-67f with a shape graphically similar to the film pieces 21. A photo filmstrip number and piece number are indicated near to the background pattern 68.

The cursor 63 is indicated at one of the thumbnail images in the film piece region 64b corresponding to the enlarged image frame 66 in the enlarged indicating frame region 64a. If the cursor 63 is shifted and set to a second one of the thumbnail images, the enlarged image frame 66 formed by enlarging the second thumbnail image is displayed in the enlarged indicating frame region 64a.

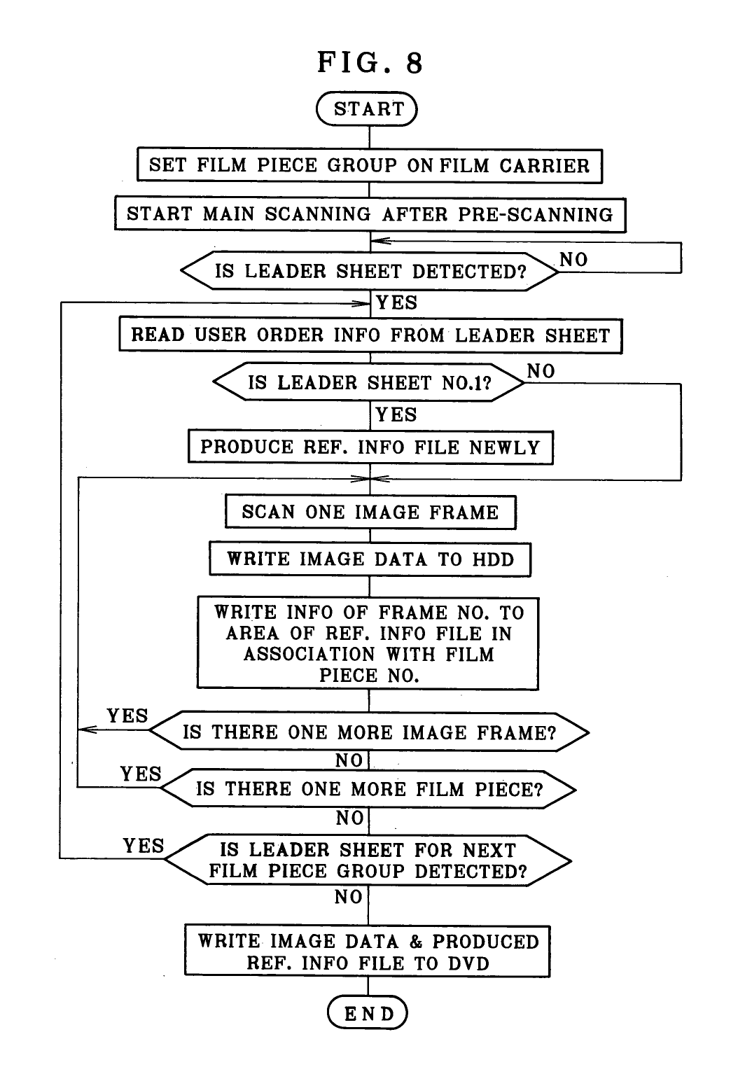

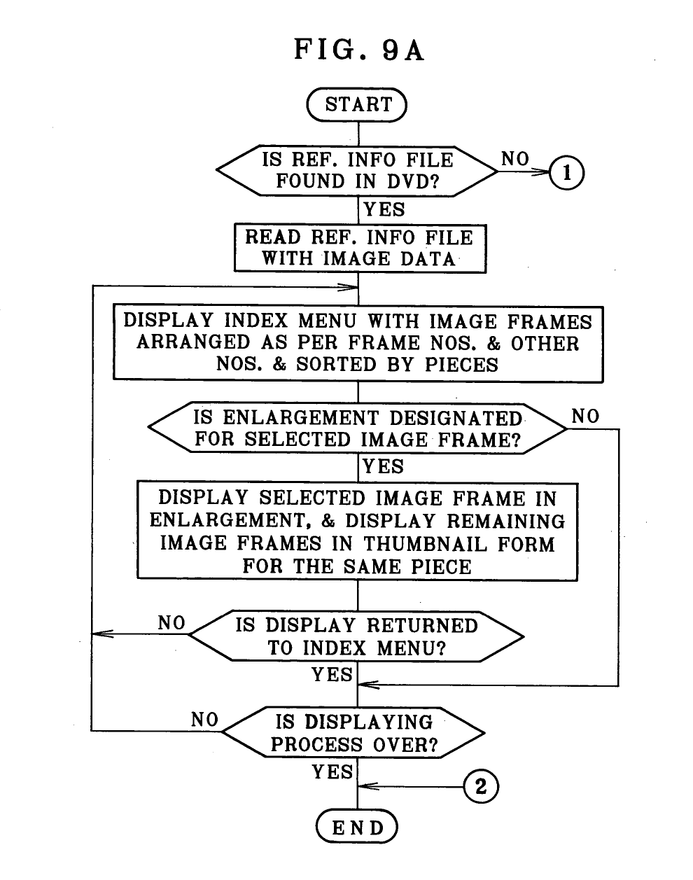

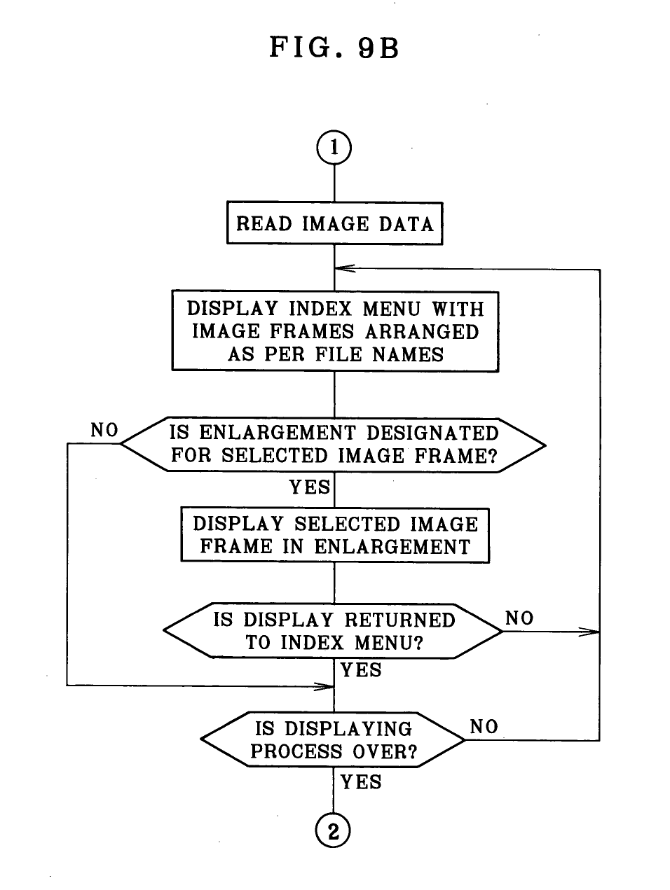

The operation of the embodiment is described by referring to flow charts of FIGS. 8, 9A and 9B. In FIG. 8, an operator at the photo digitizer 11 sets the user order film piece group 24 on the photo film carrier, the film piece group 24 including the photo film 10 from a user and in a spliced form. When a starting signal for reading is input, pre-scanning is start, for conditioning operation of reading. Then main scanning is started. When the leader sheet 26 is detected, the bar code reader 41 reads the user order information. If the leader sheet 26 is positioned as first, the digitizer CPU 45 creates a photo film reference information file.

When the edge detecting photo sensor 42 detects an end of the film pieces 21, reading of an image frame is started. Upon reading of one image frame, image data is written to RAM 46 temporarily, and then stored in the hard disk or storage device 48. Then information of the frame numbers of image frames already read is written to an area of the reference information file in association with the photo filmstrip number and the piece number. Upon completion of reading the one image frame, the user order film piece group 24 is moved forwards by a predetermined moving amount. Another frame is read in a similar manner. Thus, six image frames are read. Then a succeeding one of the film pieces 21 starts being read. When one of the film pieces 21 is next detected, the photo filmstrip number is counted up. Also, the frame number is reset. The six-frame reading is effected also for the film pieces 21 in a similar manner, to write the image data of the image frames to the hard disk 48. Information of the photo filmstrip number and the piece number is written to areas of the photo film reference information file one after another.

When the digitizer CPU 45 detects the leader sheet 26 for the second time, the digitizer CPU 45 judges that reading of the photo film 10 is completed, and resets the piece number. In a manner similar to the above, image frames are read, and additional writing to a photo film reference information file is effected. When reading of the user order film piece group 24 is finished, image data of image frames and the photo film reference information file is written to the DVD medium 12. At this time, the image displaying program 54 is written to the DVD medium 12.

The DVD medium 12 is supplied to the user as customer. The user starts up the image displaying program 54 at the computer 13, and plays the image data of image frames stored in the DVD medium 12. In FIGS. 9A and 9B, the image displaying program 54 checks whether the DVD medium 12 stores the reference information file for photo film. If no reference information file is stored, then the image displaying program 54 runs the computer 13 to display an index menu pattern in which image frames are arranged sequentially according to the file names as discernment information. Then a command signal for enlargement of an image frame is input. In response, the computer 13 changes over to the enlargement menu pattern 64, to enlarge the image frame on the display panel.

If a photo film reference information file exists, the photo film reference information file is read together with image data of image frames. The image frames are sorted according to the file names. Also, the index menu pattern 61 is indicated in which the image frames are sorted and arranged by the film pieces 21 according to the photo film reference information file. A selected one of the image frames are designated for enlargement, to change over to the enlargement menu pattern 64. The enlarged image frame 66 included in the enlarged indicating frame region 64a is displayed conspicuously. Also, the remaining image frames are displayed in a thumbnail form with the background pattern 68, the remaining image frames being included in the same film piece.

Displaying the image frames on the display panel 16 by the unit of the film piece makes distinct the relations between the frames apparently. Thus, visual interest can be enhanced by the appearance similar to viewing the film pieces 21 itself. If a user wishes printing to photographic paper, an album is used for arranging and binding pictures. It is likely that certain two pictures are arranged in reverse to their time sequence, or that one picture is disposed adjacent to another picture with which the initial picture is totally unrelated. This is because he or she does not need to arrange the pictures in the order of the time. However, it is inevitable that image frames are arranged completely by following the sequence if within a single photo filmstrip. Also, the use of the photo film reference information file can maintain the chronological relationship typically for the photo film reference information file.

A user is likely to have prints produced only when some scenes particularly impress him or her. If very little impression remains, no print or no article as records is likely to have been produced. However, digitization of all frames of the photo filmstrips makes it possible to display scenes in very close chronological relationships. The user is enabled to review and observe various image frames by considering those relationships. Even though certain images are dropped from his or her awareness or impression, they can be rediscovered or newly evaluated.

In the above embodiment, image frames are read from the photo film. However, it is possible to extract photographing date information from portions of an image frame, and write the date information to an area of the reference information file. A date image analyzer 80 in the digitizer main unit 31 is operated to receive and analyze image data of each image frame, and scans and evaluates color and density of portions of the image, for character recognition and obtaining date information imprinted inside the frame region according to the analysis of the image. This makes it possible to sort and arrange image frames according to the order of the date information at the image playing time. This is useful to users. Also, the storing of the date information as part of the reference information file can be regarded as useful for the chronological relationship between digitized image frames.

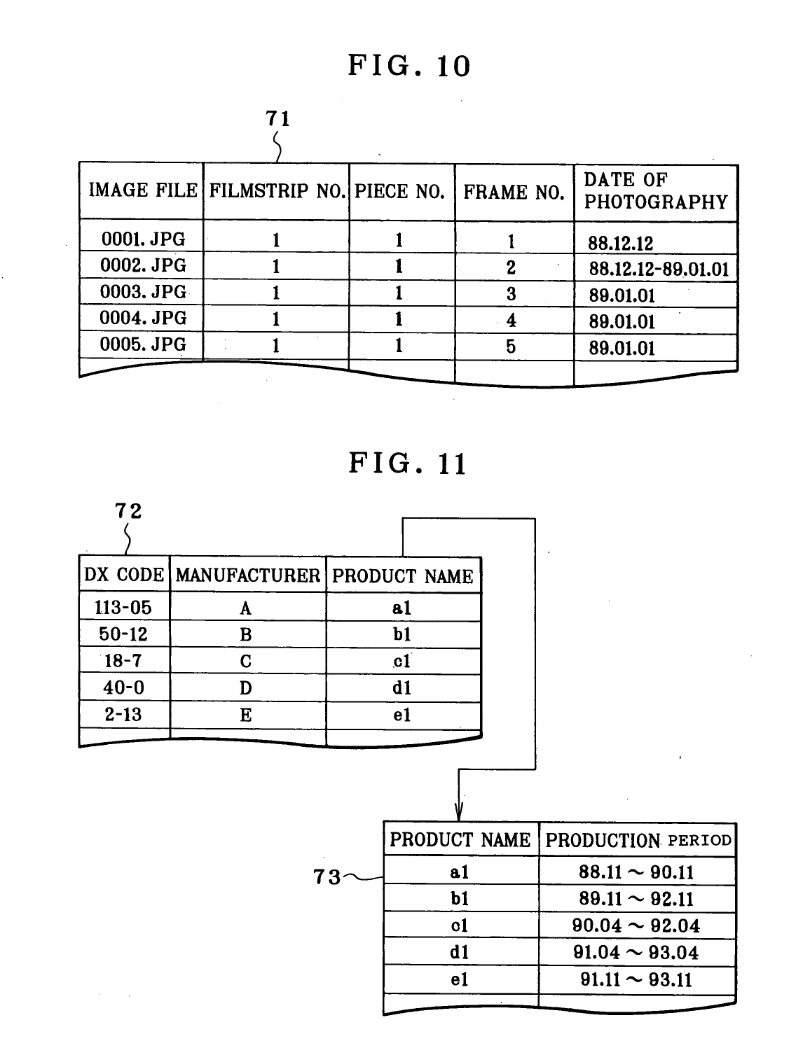

In FIG. 10, information in a photo film reference information file 71 is illustrated. An area for photographing date is formed in addition to piece discernment information. Photographing date information, obtained by the date image analyzer 80 according to the character recognition, is stored for each of the image frames as a portion of the photo film reference information file 71.

It is likely that digits of the photographing date have very similar color as that of portions of the background image. This causes failure in character recognition to detect the photographing date. For this case, a preferred process is provided, in which the unreadable date is estimated according to distinctly readable two photographing dates of two image frames directly before and after the unreadable image frame. On the single photo filmstrip, exposures are taken by following the sequence of time. Let an image frame at the frame No. 2 be unreadable. If one image frame directly preceding to the unreadable frame has the photographing date of Dec. 12, 1988, and if one image frame directly succeeding to the unreadable frame has the photographing date of Jan. 1, 1989, then the unreadable frame is detected to have a photographing date in a range between those two dates. For this case, a period of Dec. 12, 1988-Jan. 1, 1989 is mapped to this unreadable frame. Furthermore, let a third image frame have the same photographing date as a first image frame which is two frames before the third. Then a second image frame between the first and third is detected to have the same photographing date, which can be mapped to the second without an error.

A photographing date naturally can be obtained and used if clearly readable in each one of image frames. If there is no imprinting of a photographing date, a photographing date cannot be recognized in a distinct manner. However, it is conceivable to estimate a period or term in which an actual photographing date is included. This is subsidiarily useful in sorting image frames in addition to clearly readable photographing dates.

To determine a calendrical period of photography of an image frame, the use of the above DX code is conceivable. It is necessary to use the DX code at the time of printing. In general, operators at photo laboratories for printing have been enabled to use the information by considering relationships between the DX code and information including a name of a manufacturer, a product name and the like. It is possible to use the DX code as useful information in the photo digitizing system, so as to find the product name of the photographic film by use of the DX code.

In FIG. 11, a DX code table 72 is created as data table of a DX code and a photo film type related thereto. Also, a production history data table 73 is created as data table of a production period and a photo film type related thereto according to previous research of production periods. One of the photo film types is derived from the DX code table 72, and used as a key to find a production period by referring to the production history data table 73. This is based on a useful life or valid term of photo film. It is supposed that most of users in general use their photo film before the expiration of the useful life. In general, a useful life or valid term of photo film is determined by addition of a predetermined number of years to a production date. Thus, it is possible to estimate a calendrical period of photography as a term starting on the production date and ending on a date that is obtained by addition of a predetermined number of years to a final date of the production term.

Let a production period be from November of 1988 to November of 1990. Let the photo filmstrip have a useful life or valid term of two years. Then a calendrical period of photography is estimated from November of 1988 to November of 1992. The calendrical period of photography is mapped to the respective image frames. Note that the DX code table 72 and the production history data table 73 are stored in the hard disk or storage device 48 of the photo digitizer 11. At the time of producing image files of image frames, the digitizer CPU 45 runs the period determining program to determine the calendrical period of photography.

To estimate a production period effectively according to a DX code, a production period table requires creating. However, a search of production periods of all known manufacturers is extremely difficult. For example, it is nearly impossible to find detailed information of foreign products or unfamiliar manufacturers.

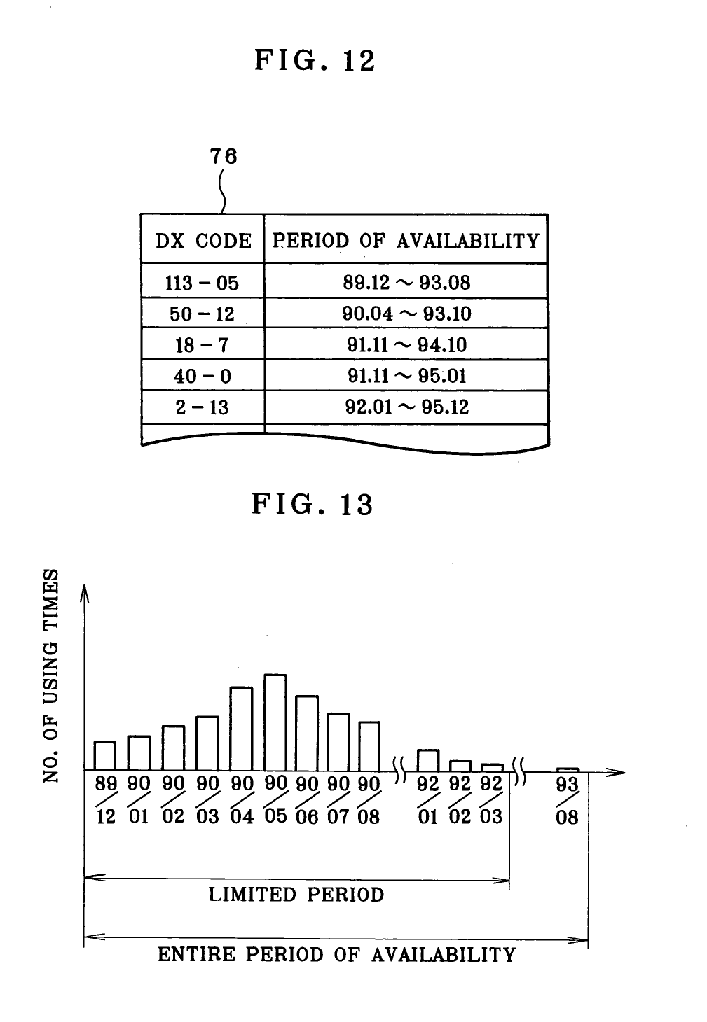

Another preferred embodiment is directed to use an availability period of the photo filmstrip as calendrical period of photography, in place of its production period. To estimate the availability period, a DX code of the photo filmstrip is utilized to estimate photographing dates indirectly. Initially, sampling of data is required. Specifically, partial images in various image frames having photographing dates are read, analyzed by character recognition, and stored for sampling. DX codes of photo filmstrips are read. Information of relationships between the photographing dates and the DX codes are stored empirically. As a result, an availability history data table 76 of information which includes availability periods is created for relationships between the DX codes and the periods of availability of the negative photo films. See FIG. 12. If there is a photo filmstrip without a partial image of a photographing date, then the DX code of the photo filmstrip is used as a key for addressing in the availability history data table 76 to extract the availability period, which is regarded as a calendrical period of photography. This makes it possible to determine the period of photography even if the photo filmstrip does not have information of a production period or a photographing date. It is preferable to store the availability history data table 76 in the hard disk or storage device 48 of the photo digitizer 11 as well as the production history data table 73 described above, for the digitizer CPU 45 to execute determination of the period of photography.

FIG. 13 is a graph illustrating a distribution of times of use of photo films which have DX codes and used in an entire period of availability. The entire period of availability is from December of 1989 to August of 1993. In contrast, most of the users use the photo films in a partial period included in the entire period of availability from December of 1989 to March of 1992. According to the distribution, it is possible to find a calendrical period of photography by specifying such a limited period. This use of the limited period is advantageous in shortening a period. If a period is long without being shortened, the period will not be useful in view of sorting image frames.

Note that the period determining method of determination by sampling and storing the relations between the DX codes and the photographing dates is an auxiliary process used only when the DX code is not found in the production history data table 73. However, this method of determination by sampling and storing can be used as a period determining method of photo filmstrips of which the DX code is found in the production history data table 73.

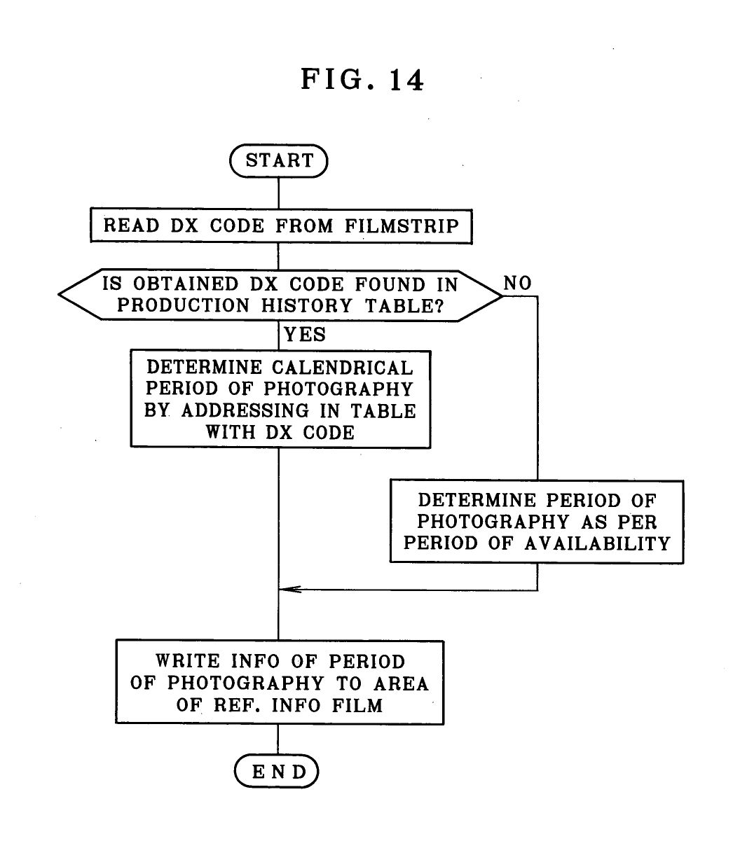

FIG. 14 is a flow chart of determining a calendrical period of photography according to a DX code. If no photographing date is imprinted in an image frame, a calendrical period of photography of the photo film is determined according to a DX code of the photo film. At first, existence or lack of a DX code is checked in the production history data table 73. If a DX code is found to exist, then a production period is derived. Then a calendrical period of photography is determined according to the production period. In contrast, if a DX code does not exist, then a period of availability is derived by referring to the availability history data table 76 of the DX code and the period of availability by addressing the DX code as a key. Then the derived period of availability is regarded as the calendrical period of photography. The calendrical period of photography is stored in an area of the photo film reference information file 71 for photographing date information.

In the above embodiment, the photo film is negative. However, the photo film according to the invention may be a positive film on which positive images of image frames are created.

In the above embodiment, the image displaying program or software is written to the DVD medium. However, the DVD medium may not store the image displaying program. Instead, a storage device in the computer is used for installing the image displaying program, which is run for displaying operation. In the above embodiment, the personal computer is used for displaying images. However, a general-purpose computer may not be used. An image displaying apparatus of the invention may have a specialized construction distinct from a general-purpose computer.

Examples of the DVD medium 12 used herein can be a type recordable at one time, such as DVD−R and DVD+R, and also a rewritable type, such as DVD−DW, DVD+DW and DVD−RAM. Furthermore, any suitable storage media may be used, including a CD medium, MO medium, micro drive (trade name), blue ray disk (or blu-ray disc), and other optical information recording media.

Although the present invention has been fully described by way of the preferred embodiments thereof with reference to the accompanying drawings, various changes and modifications will be apparent to those having skill in this field. Therefore, unless otherwise these changes and modifications depart from the scope of the present invention, they should be construed as included therein.

1. An image data recording method of recording image data of an image frame to a storage medium, comprising steps of:
reading said image frame from a film piece by a scanner to obtain said image data, said film piece being included in a plurality of film pieces defined by splitting of photo film, said film piece having a plurality of said image frame which is readable by said scanner; and
writing said image data to said storage medium together with piece discernment information for discernment of said film piece.

2. An image data recording method as defined in claim 1, wherein said piece discernment information is constituted by counted information of said film piece according to counting toward a front or rear end of said photo film in serial arrangement of said plural film pieces in an unsplit form of said photo film.

3. An image data recording method as defined in claim 2, further comprising a step of writing photo film discernment information of discernment of said photo film to said storage medium.

4. An image data recording method as defined in claim 2, further comprising steps of:
obtaining information of a photographing date of said image frames by analyzing said image data according to character recognition; and
writing said information of said photographing date to said storage medium.

5. An image data recording method as defined in claim 4, further comprising steps of:
in case of failure of determining said photographing date, determining an estimated photographing period; and
writing information of said estimated photographing period being determined to said storage medium.

6. An image data recording method as defined in claim 5, wherein said estimated photographing period is determined by analyzing type information constituted by a type of said photo film.

7. An image data recording method as defined in claim 6, further comprising steps of:
in case of failure of determining said photographing date, determining a production period according to said type information, said production period being regarded as said estimated photographing period; and
in case of failure of determining said production period, determining an availability period according to said type information, said availability period being regarded as said estimated photographing period.

8. An image data recording method as defined in claim 1, wherein said storage medium comprises an optical information recording medium.

9. An image data recording apparatus for recording image data of an image frame to a storage medium, comprising:
a scanner for reading said image frame from a film piece and for conversion into said image data, said film piece being included in a plurality of film pieces defined by splitting of photo film, said film piece having a plurality of said image frame which is readable by scanner reading; and
an information recorder for writing said image data to said storage medium together with piece discernment information for discernment of said film piece.

10. An image data recording apparatus as defined in claim 9, wherein said piece discernment information is constituted by counted information of said film piece according to counting toward a front or rear end of said photo film in serial arrangement of said plural film pieces in an unsplit form of said photo film.

11. An image data recording apparatus as defined in claim 10, wherein said scanner further comprises:
a transporting mechanism for transporting a film piece group of said film pieces in series in a form of said photo film before cutting in said film pieces and connected by tape splicing;
an edge sensor for detecting at least one of front and rear ends of said film pieces in said film piece group being transported; and
a controller for counting said film pieces upon an output of said edge sensor, and for assigning said piece discernment information to said film pieces according to a result of counting.

12. An image data recording apparatus as defined in claim 11, wherein said controller counts said image frames being read in a range of said film pieces, and assigns image frame discernment information to said image frames according to a result of counting, said image frame discernment information being written to said storage medium with said piece discernment information.

13. An image data recording apparatus as defined in claim 9, further comprising a date image analyzer for obtaining information of a photographing date of said image frames by analyzing said image data according to character recognition, wherein said information recorder writes said information of said photographing date to said storage medium.

14. An image data recording apparatus as defined in claim 13, further comprising a period estimating unit, operated in case of failure of determining said photographing date, for determining an estimated photographing period, wherein information of said estimated photographing period being determined is written to said storage medium.

15. An image data recording apparatus as defined in claim 14, wherein said period estimating unit includes a storage device for storing first and second data tables;
said first data table is constituted by information of a production period in combination with type information of one type of said photo film of which said production period is recognizable;
said second data table is constituted by information of a pre-estimated availability period in combination with said type information of said type of said photo film irrespective of recognition of said production period thereof;
said controller refers to said first data table for determining said production period according to said type information, and in case of failure of determining with said first data table, refers to said second data table for determining said availability period according to said type information, either one of said production period and said availability period being adapted to determining said estimated photographing period.

16. An image displaying method of displaying image frames of photo film on a display panel, comprising a step of:
arranging said image frames per film piece on said display panel, said film piece being defined by splitting of said photo film after being developed photographically.

17. An image displaying method as defined in claim 16, further comprising steps of:
reading image data of said image frames from a storage medium; and
sorting said image data per said film piece.

18. An image displaying method as defined in claim 17, further comprising a step of reading piece discernment information from said storage medium, said piece discernment information being adapted to sorting of said image data per said film piece associated therewith.

19. An image displaying method as defined in claim 18, wherein in said arranging step, at least one film piece region is indicated on said display panel, to extend horizontally, and display a series of said image frames included in said film piece.

20. An image displaying method as defined in claim 19, wherein said display panel further displays photo film discernment information of said photo film and said piece discernment information in association with said film piece region.

21. An image displaying method as defined in claim 20, wherein said at least one film piece region comprises plural film piece regions arranged vertically in series.

22. An image displaying method as defined in claim 19, wherein in said arranging step, an enlarged indicating frame region is indicated on said display panel, to display a designated one of said image frames indicated in said film piece region in an enlarged size.

23. An image displaying method as defined in claim 19, further comprising a step of determining whether said piece discernment information is stored in said storage medium; and
wherein in case of failure of determining said piece discernment information, said image frames are arranged on said display panel according to discernment information of said image data.

24. An image displaying method as defined in claim 19, wherein said storage medium comprises an optical information recording medium.

25. An image displaying apparatus for displaying an image frame read from a storage medium,
wherein piece discernment information is associated with respectively said image frame for discernment of a film piece, said film piece is included in a plurality of film pieces defined by splitting of photo film, said film piece has a plurality of said image frame of which image data is stored in said storage medium after scanner reading, said image displaying apparatus comprising:
a controller for arranging said plural image frames from said storage medium per said film pieces according to said piece discernment information; and
a display panel, controlled by said controller, for displaying said plural image frames in a sorted manner per said film pieces.
